(19) United States
(12) Patent Application Publication
(10) Pub. No.: US 2026/0344023 A1
(43) Pub. Date: Oct. 29, 2026

(54) SEMICONDUCTOR DEVICE

(71) Applicant: Dynax Semiconductor, Inc., Suzhou (CN)

(72) Inventors: Linlin SUN, Suzhou (CN); Xinchuan ZHANG, Suzhou (CN)

(73) Assignee: Dynax Semiconductor, Inc., Suzhou (CN)

(21) Appl. No.: 19/718,054

(22) Filed: Jun. 24, 2026

Related U.S. Application Data
(63) Continuation of application No. PCT/CN2024/142071, filed on Dec. 25, 2024.

(30) Foreign Application Priority Data
Dec. 25, 2023 (CN) 202311798023.7
Dec. 25, 2023 (CN) 202311799292.5

(51) Int. Cl. H10D 84/80; H10D 1/00; H10D 1/47; H10D 30/01; H10D 30/47; H10D 62/10; H10D 64/27

(52) U.S. Cl. CPC H10D 84/817; H10D 1/47; H10D 30/475; H10D 64/519; H10D 1/021; H10D 30/015; H10D 62/102

(57) ABSTRACT

A semiconductor device includes: a substrate; an epitaxial structure located on a side of the substrate; an electrode structure located on a side of the epitaxial structure away from the substrate; and at least one odd-mode resistor located outside the first active region and electrically connected to the electrode structure. Each odd-mode resistor of the at least one odd-mode resistor includes a first resistor electrode and a second resistor electrode. In a same odd-mode resistor, the first resistor electrode and the second resistor electrode both form ohmic contact with the two-dimensional electron gas in the second active region, and along an arrangement direction of the first resistor electrode and the second resistor electrode, a two-dimensional-electron-gas conductive channel exists between the first resistor electrode and the second resistor electrode.

### CROSS-REFERENCE TO RELATED APPLICATIONS

This application is a continuation of International Application No. PCT/CN2024/142071, filed on Dec. 25, 2024, which claims priority to Chinese Patent Application No. 202311799292.5, filed on Dec. 25, 2023, and Chinese Patent Application No. 202311798023.7, filed on Dec. 25, 2023. All of the aforementioned applications are incorporated herein by reference in their entireties.

### TECHNICAL FIELD

The present disclosure relates to the field of microelectronic technologies, and in particular to a semiconductor device.

### BACKGROUND

Gallium Nitride High Electron Mobility Transistors (GaN HEMTs) have excellent characteristics such as wide bandgap and high mobility, making them suitable for manufacturing high-temperature, high-frequency, high-voltage, and high-power devices. They can be widely used in the radio frequency microwave field and the power electronics field. Currently, they are one of the research hotspots in the semiconductor device field.

At present, 5G communication demands increasingly higher bandwidth and operating frequency for semiconductor chips. GaN HEMTs utilize a two-dimensional electron gas formed at a heterojunction of an epitaxial structure to create a high electron mobility device, which can be better applied in high-frequency, high-voltage, and high-power fields, naturally receiving favor in the 5G communication field.

For Gallium Nitride radio frequency power amplifiers, improving device power, gain, and efficiency is a constant pursuit of Gallium Nitride chips. However, to achieve relatively high power, oscillation usually occurs, thereby affecting device performance or stability. Therefore, how to improve the stability of semiconductor devices is an urgent problem to be solved.

### SUMMARY

The present disclosure provides a semiconductor device to suppress oscillation, thereby improving stability of the semiconductor device.

Embodiments of the present disclosure provide a semiconductor device. The semiconductor device has a first active region and a second active region spaced apart from each other, and a passive region surrounding the first active region and the second active region. The semiconductor device includes: a substrate; an epitaxial structure located on a side of the substrate, the epitaxial structure being provided with a two-dimensional electron gas, and the two-dimensional electron gas existing in the first active region and the second active region; an electrode structure located on a side of the epitaxial structure away from the substrate, a portion of the electrode structure being located in the first active region, and another portion of the electrode structure being located in the passive region; and at least one odd-mode resistor located outside the first active region and electrically connected to the electrode structure. Each of the at least one odd-mode resistor includes a first resistor electrode and a second resistor electrode, at least a portion of the first resistor electrode and at least a portion of the second resistor electrode are both located in the second active region, and in a same odd-mode resistor, the first resistor electrode and the second resistor electrode both form ohmic contact with the two-dimensional electron gas in the second active region; and along an arrangement direction of the first resistor electrode and the second resistor electrode, a two-dimensional-electron-gas conductive channel exists between the first resistor electrode and the second resistor electrode.

Optionally, a distance between the first resistor electrode and the second resistor electrode is d, and extension lengths of the first resistor electrode and the second resistor electrode are both w; a contact resistance of the first resistor electrode is Rc1, a contact resistance of the second resistor electrode is Rc2, and a sheet resistance of the two-dimensional electron gas between the first resistor electrode and the second resistor electrode is Rsh; and a resistance value R of the odd-mode resistor is equal to Rc1+Rc2+Rsh·d/W.

Optionally, the at least one odd-mode resistor includes at least one first odd-mode resistor, the electrode structure includes a gate electrode structure, the gate electrode structure includes at least one gate electrode and a gate supply electrode, and each of the at least one gate electrode is spaced apart from the gate supply electrode; and the first resistor electrode of the at least one first odd-mode resistor is electrically connected to the at least one gate electrode, and the second resistor electrode of the at least one first odd-mode resistor is electrically connected to the gate supply electrode.

Optionally, the electrode structure further includes an ohmic electrode structure, the ohmic electrode structure includes an ohmic electrode and an ohmic supply electrode connected to each other; each of at least one of the gate supply electrode or the ohmic supply electrode includes at least two supply sub-portions, any two adjacent supply sub-portions of the at least two supply sub-portions are spaced apart from each other, and the at least one odd-mode resistor further includes at least one second odd-mode resistor; and in a same second odd-mode resistor, the first resistor electrode is electrically connected to one of the at least two supply sub-portions, and the second resistor electrode is electrically connected to another of the at least two supply sub-portions.

Optionally, the at least one odd-mode resistor includes at least one second odd-mode resistor, the electrode structure includes at least one electrode and at least one supply electrode electrically connected to the at least one electrode, each of the at least one supply electrode includes at least two supply sub-portions, and any two adjacent supply sub-portions of the at least two supply sub-portions are spaced apart from each other; and in a same second odd-mode resistor, the first resistor electrode is electrically connected to one of the at least two supply sub-portions, and the second resistor electrode is electrically connected to another of the at least two supply sub-portions.

In the technical solutions of the embodiments of the present disclosure, the odd-mode resistor includes the first resistor electrode and the second resistor electrode. The first resistor electrode and the second resistor electrode both form the ohmic contact with the two-dimensional electron gas, and the two-dimensional-electron-gas conductive channel exists between the first resistor electrode and the second resistor electrode, so that the first resistor electrode and the second resistor electrode can be channel-conducted. In addition, the electrode structure is electrically connected to the odd-mode resistor, thereby implementing electrical connection of the entire electrode structure. Therefore, the odd-mode resistor can dissipate energy of an odd-mode signal, thereby suppressing generation of odd-mode oscillation and further improving stability of the semiconductor device.

### BRIEF DESCRIPTION OF THE DRAWINGS

FIG. 1 is a schematic top view of a semiconductor device according to an embodiment of the present disclosure.

FIG. 2 is a schematic cross-sectional view of the semiconductor device shown in FIG. 1 taken along section line A-A′.

FIG. 3 is a schematic top view of a semiconductor device according to an embodiment of the present disclosure.

FIG. 4 is a schematic top view of a semiconductor device according to an embodiment of the present disclosure.

FIG. 5 is a schematic top view of a semiconductor device according to an embodiment of the present disclosure.

FIG. 6 is a schematic top view of a semiconductor device according to an embodiment of the present disclosure.

FIG. 7 is a schematic cross-sectional view of the semiconductor device shown in FIG. 6 taken along section line A-A′.

FIG. 8 is a schematic cross-sectional view of the semiconductor device shown in FIG. 6 taken along section line B-B′.

FIG. 9 is a schematic top view of a semiconductor device according to an embodiment of the present disclosure.

FIG. 10 is a schematic flowchart of a method for manufacturing a semiconductor device according to an embodiment of the present disclosure.

### DETAILED DESCRIPTION OF THE EMBODIMENTS

It should be noted that the terms “first”, “second”, and the like in the specification, claims, and drawings of the present disclosure are used to distinguish similar objects, and are not necessarily used to describe a specific order or sequence. It should be understood that data so used may be interchangeable under appropriate circumstances, so that the embodiments of the present disclosure described herein may be implemented in orders other than those illustrated or described herein. In addition, the terms “comprising”, “including” and any variation thereof are intended to cover non-exclusive inclusion.

As described in the Background, for Gallium Nitride radio frequency power amplifiers improving device power, gain, and efficiency is a constant pursuit of Gallium Nitride chips. However, in order to achieve relatively high power, multiple gate fingers are usually designed, which easily forms long feedback loops in different gate fingers and drains, thereby causing oscillation. Such oscillation is referred to as odd-mode oscillation. Due to the presence of odd-mode oscillation, device performance or stability is affected. Therefore, how to improve stability of a semiconductor device is a problem urgently needing to be solved at present.

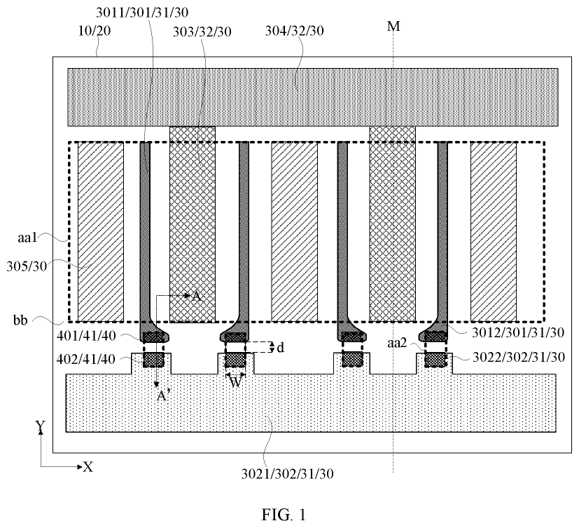

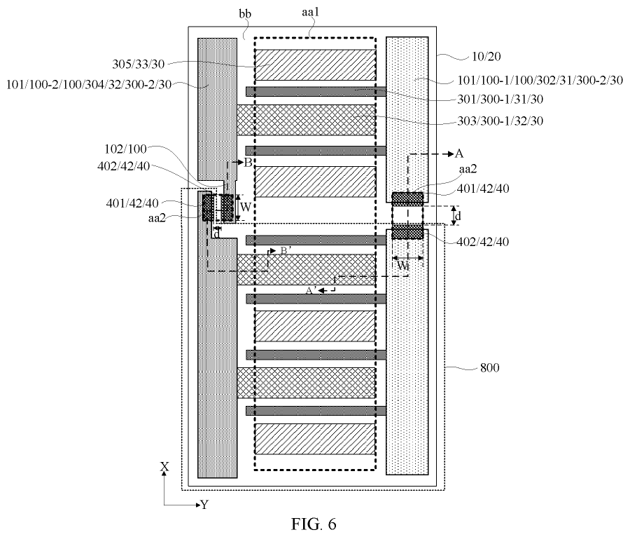

To solve the above problem, embodiments of the present disclosure provide a semiconductor device. FIG. 1 is a schematic top view of a semiconductor device according to an embodiment of the present disclosure; and FIG. 6 is a schematic top view of a semiconductor device according to an embodiment of the present disclosure. As shown in FIGS. 1 and 6, the semiconductor device has a first active region aa1 and a second active region aa2 that are spaced apart from each other, and a passive region bb surrounding the first active region aa1 and the second active region aa2. A two-dimensional electron gas exists in the first active region aa1 and the second active region aa2, and the second active region aa2 may be understood as a region, provided in the passive region bb, in which the two-dimensional electron gas is retained.

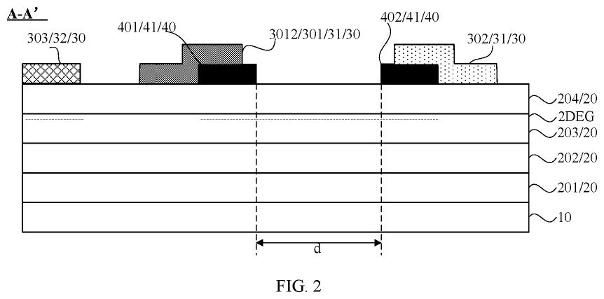

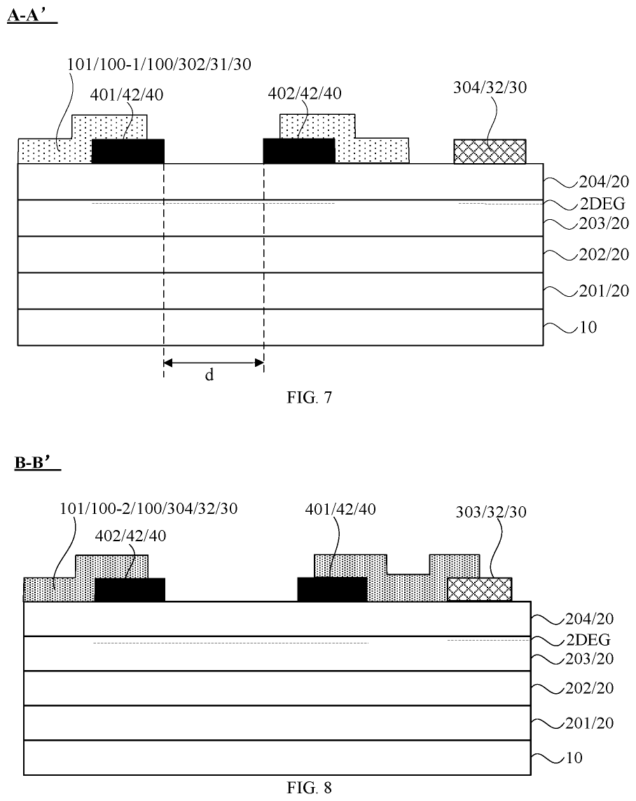

FIG. 2 is a schematic cross-sectional view of the semiconductor device shown in FIG. 1 taken along section line A-A′; and FIG. 7 is a schematic cross-sectional view of the semiconductor device shown in FIG. 6 taken along section line A-A′. As shown in FIGS. 1, 2, 6, and 7, the semiconductor device includes a substrate 10, an epitaxial structure 20, an electrode structure 30, and at least one odd-mode resistor 40. The epitaxial structure 20 is located on a side of the substrate 10. The epitaxial structure 20 is provided with a two-dimensional electron gas (2DEG), and the two-dimensional electron gas exists in the first active region aa1 and the second active region aa2. The electrode structure 30 is located on a side of the epitaxial structure 20 away from the substrate 10. A portion of the electrode structure 30 is located in the first active region aa1, and another portion of the electrode structure 30 is located in the passive region bb. The at least one odd-mode resistor 40 is electrically connected to the electrode structure 30 and located outside the first active region aa1. Each odd-mode resistor 40 of the at least one odd-mode resistor 40 includes a first resistor electrode 401 and a second resistor electrode 402. At least a portion of the first resistor electrode 401 and at least a portion of the second resistor electrode 402 are both located in the second active region aa2. In a same odd-mode resistor 40, the first resistor electrode 401 and the second resistor electrode 402 both form ohmic contact with the two-dimensional electron gas in the second active region aa2, and along an arrangement direction of the first resistor electrode 401 and the second resistor electrode 402, a two-dimensional-electron-gas conductive channel exists between the first resistor electrode 401 and the second resistor electrode 402.

The at least a portion of the first resistor electrode 401 and the at least a portion of the second resistor electrode 402 being located in the second active region aa2 may be understood as meaning that a portion of the first resistor electrode 401 and a portion of the second resistor electrode 402 are both located in the second active region aa2, while another portion of the first resistor electrode 401 and another portion of the second resistor electrode 402 are both located in the passive region bb; alternatively, the entire first resistor electrode 401 and the entire second resistor electrode 402 are both located in the second active region aa2. FIGS. 1 and 6 merely schematically show a positional relationship between the first resistor electrode 401 and the second active region aa2, and a positional relationship between the second resistor electrode 402 and the second active region aa2.

Generally, the two-dimensional electron gas in the passive region bb is depleted by ion implantation or the like. In the embodiments of the present disclosure, the odd-mode resistor 40 is provided in a region of the passive region bb where the two-dimensional electron gas is retained (that is, the second active region aa2), namely, the two-dimensional electron gas in the region of the passive region bb where the odd-mode resistor 40 is provided is retained, so that the odd-mode resistor 40 forms ohmic contact with the two-dimensional electron gas.

For example, the substrate 10 may be formed of one of silicon, sapphire, silicon carbide, or gallium arsenide. The epitaxial structure 20 located on the side of the substrate 10 may be formed of one or more group III-V nitrides such as gallium nitride, aluminum gallium nitride, indium gallium nitride, aluminum nitride, or indium aluminum gallium nitride.

For example, with continued reference to FIGS. 2 and 7, the epitaxial structure 20 may include a nucleation layer 202, a buffer layer 203, a channel layer 204, and a barrier layer 205; and the channel layer 204 and the barrier layer 205 may form a heterojunction structure.

For example, with continued reference to FIGS. 2 and 7, a material of the nucleation layer 202 may be aluminum nitride, and the nucleation layer 202 is located between the substrate 10 and the buffer layer 203, so as to bond a semiconductor material layer to be subsequently grown.

For example, with continued reference to FIGS. 2 and 7, the buffer layer 203 is located on a side of the substrate 10. A material of the buffer layer 203 may be gallium nitride, and the buffer layer 203 may include iron atoms, which is beneficial to achieving high-resistance performance of the buffer layer 203, thereby ensuring that vertical leakage can be blocked and improving pinch-off performance of the semiconductor device.

For example, with continued reference to FIGS. 2 and 7, a material of the channel layer 204 may be a group III nitride, for example AlxGa1-xN, where 0<=x<1. For example, x=0 indicates that the material of the channel layer 204 is GaN. The material of the channel layer 204 may alternatively be another group III nitride; for example, the material of the channel layer 204 may be InGaN or AlInGaN. The channel layer 204 may be undoped or unintentionally doped. The channel layer 204 may also be a multilayer structure; for example, the channel layer 204 may be a superlattice or a combination of GaN and AlGaN.

For example, a material of the barrier layer 205 may be AlN, AlInN, AlGaN, or AlInGaN. The barrier layer 205 has a sufficient thickness and a sufficiently high Al composition, so that significant carrier concentration is formed by doping at an interface between the channel layer 204 and the barrier layer 205.

For example, with continued reference to FIGS. 2 and 7, due to a bandgap difference between the barrier layer 205 and the channel layer 204 and a piezoelectric polarization effect at an interface between the barrier layer 205 and the channel layer 204, a two-dimensional electron gas is formed at the junction between the channel layer 204 and the barrier layer 205.

It may be understood that the epitaxial structure 20 may further include a cap layer, and the cap layer is located on a surface of the barrier layer 205 away from the substrate 10. The cap layer can reduce surface states, so as to reduce surface leakage of a subsequent semiconductor device and suppress current collapse, thereby improving stability and reliability of the epitaxial structure 20 and the semiconductor device.

In the semiconductor device provided in the embodiments of the present disclosure, each odd-mode resistor 40 includes a first resistor electrode 401 and a second resistor electrode 402. The first resistor electrode 401 and the second resistor electrode 402 both form ohmic contact with the two-dimensional electron gas, and a two-dimensional-electron-gas conductive channel exists between the first resistor electrode 401 and the second resistor electrode 402, so that the first resistor electrode 401 and the second resistor electrode 402 can be channel-conducted. In addition, the electrode structure 30 is electrically connected to the odd-mode resistor 40, thereby implementing electrical connection of the entire electrode structure 30. Therefore, the odd-mode resistor 40 can dissipate an odd-mode signal in the electrode structure 30, thereby suppressing generation of odd-mode oscillation and further improving stability of the semiconductor device.

In addition, compared with manufacturing a thin-film resistor, during the fabrication of the odd-mode resistor 40 in the present disclosure, no additional metal layer needs to be introduced, thereby reducing process steps in the manufacturing process and further reducing complexity and manufacturing cost of the semiconductor device.

Optionally, with continued reference to FIGS. 1 and 6, in a same odd-mode resistor 40, a distance between the first resistor electrode 401 and the second resistor electrode 402 is d, and extension lengths of the first resistor electrode 401 and the second resistor electrode 402 are both w; a contact resistance of the first resistor electrode 401 is Rc1, a contact resistance of the second resistor electrode 402 is Rc2, and a sheet resistance of the two-dimensional electron gas between the first resistor electrode 401 and the second resistor electrode 402 is Rsh; and a resistance value of the odd-mode resistor 40 is R=Rc1+Rc2+Rsh·d/W.

It should be understood that Rc refers to ohmic contact resistance, that is, Rc1 is ohmic contact resistance between the first resistor electrode 401 and the two-dimensional electron gas, and Rc2 is ohmic contact resistance between the second resistor electrode 402 and the two-dimensional electron gas.

Specifically, for a determined process platform, the contact resistances Rc1 and Rc2 of the first resistor electrode 401 and the second resistor electrode 402 and the sheet resistance Rsh of the two-dimensional electron gas between the first resistor electrode 401 and the second resistor electrode 402 are fixed. Therefore, the resistance value of the odd-mode resistor 40 can be changed by adjusting the distance d between the first resistor electrode 401 and the second resistor electrode 402 and/or adjusting the extension lengths w of the first resistor electrode 401 and the second resistor electrode 402, so that diversified design of the resistance value of the odd-mode resistor 40 can be implemented by adjusting the resistance value of the odd-mode resistor 40, thereby achieving different suppression effects and further satisfying requirements in various different scenarios.

It should be noted that the resistance value of the odd-mode resistor 40 may be designed according to performance and stability of the semiconductor device, so as to improve flexibility in providing the odd-mode resistor 40. For example, the resistance value of the odd-mode resistor 40 may be several ohms to several tens of ohms.

The following describes different semiconductor devices of the present disclosure by way of example based on two embodiments.

A semiconductor device is described below based on a first embodiment. The first embodiment is described from the perspective that the at least one odd-mode resistor 40 includes at least one first odd-mode resistor 41 and at least one second odd-mode resistor 42. As shown in FIGS. 1 to 5, a structure of the semiconductor device is specifically as follows.

The electrode structure 30 includes a gate electrode structure 31. The gate electrode structure 31 includes at least one gate electrode 301 and a gate supply electrode 302, and each gate electrode 301 of the at least one gate electrode 301 is spaced apart from the gate supply electrode 302. Each first odd-mode resistor 41 of the at least one first odd-mode resistor 41 includes a first resistor electrode 401 and a second resistor electrode 402. The first resistor electrode 401 and the second resistor electrode 402 both form ohmic contact with the two-dimensional electron gas, and along an arrangement direction of the first resistor electrode 401 and the second resistor electrode 402, a two-dimensional-electron-gas conductive channel exists between the first resistor electrode 401 and the second resistor electrode 402, that is, the first resistor electrode 401 and the second resistor electrode 402 are electrically connected through the two-dimensional electron gas. The first resistor electrode 401 of the at least one first odd-mode resistor 41 is electrically connected to the at least one gate electrode 301, and the second resistor electrode 402 of the at least one first odd-mode resistor 41 is electrically connected to the gate supply electrode 302.

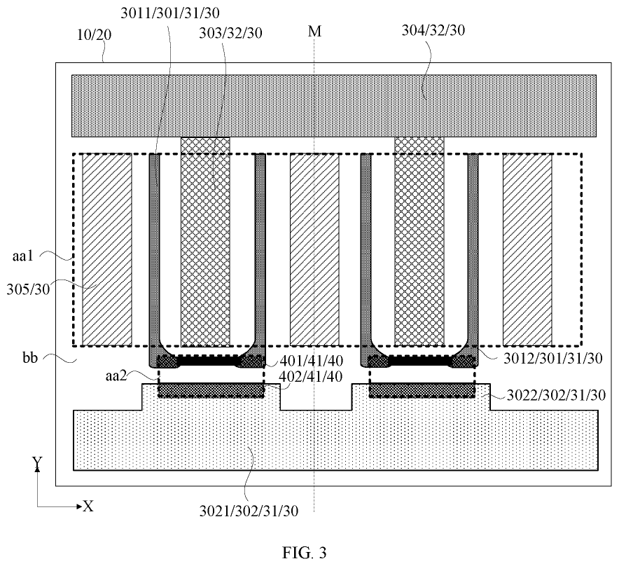

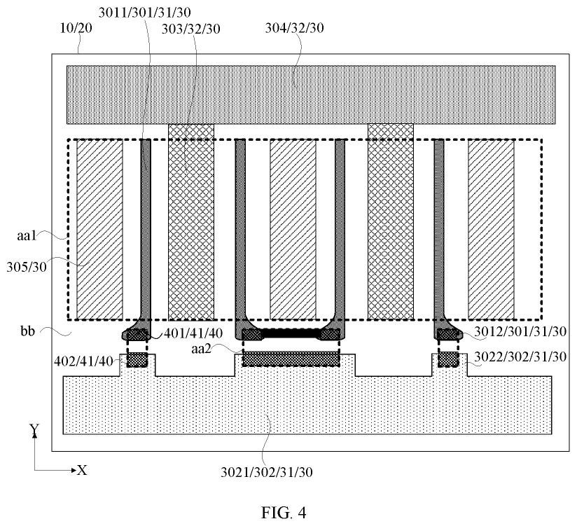

In one example, as shown in FIGS. 3 and 4, in a case that the at least one gate electrode 301 includes a plurality of gate electrodes 301, in a same first odd-mode resistor 41, the first resistor electrode 401 is electrically connected to at least one gate electrode 301 of the plurality of gate electrodes 301, and the second resistor electrode 402 is electrically connected to the gate supply electrode 302. That is, one gate electrode 301 corresponds to one first odd-mode resistor 41, or a plurality of gate electrodes 301 correspond to one first odd-mode resistor 41.

In another example, as shown in FIG. 1, in a case that the at least one gate electrode 301 includes a plurality of gate electrodes 301, a first odd-mode resistor 41 is provided between each gate electrode 301 of the plurality of gate electrodes 301 and the gate supply electrode 302. That is, each gate electrode 301 corresponds to one first odd-mode resistor 41.

The gate supply electrode 302 may be understood as a gate pad. Each gate electrode 301 is spaced apart from the gate supply electrode 302, that is, each gate electrode 301 is not in contact with the gate supply electrode 302, but a gap exists therebetween.

The first odd-mode resistor 41 is provided in a region of the passive region bb where the two-dimensional electron gas is retained, namely, the two-dimensional electron gas in the region of the passive region bb where the first odd-mode resistor 41 is provided is retained, so that the first odd-mode resistor 41 forms ohmic contact with the two-dimensional electron gas. It should be noted that both the gate electrode 301 and the gate supply electrode 302 have zero contact with the two-dimensional electron gas in the region where the first odd-mode resistor 41 is located. That is, when the gate electrode 301 and the gate supply electrode 302 are manufactured, they cannot completely wrap the first resistor electrode 401 and the second resistor electrode 402 of the first odd-mode resistor 41, but at least expose a side surface of the first resistor electrode 401 of the first odd-mode resistor 41 and a side surface of the second resistor electrode 402 of the first odd-mode resistor 41, the two side surfaces being adjacent to each other, so as to ensure that the first resistor electrode 401 and the second resistor electrode 402 of the first odd-mode resistor 41 form complete contact with the two-dimensional electron gas, and to avoid contact between the gate electrode 301 and the two-dimensional electron gas, and contact between the gate supply electrode 302 and the two-dimensional electron gas. Further, along the arrangement direction of the first resistor electrode 401 and the second resistor electrode 402, a two-dimensional-electron-gas conductive channel exists between the first resistor electrode 401 and the second resistor electrode 402, so that the first resistor electrode 401 and the second resistor electrode 402 can be channel-conducted.

In a same first odd-mode resistor 41, the first resistor electrode 401 is electrically connected to the at least one gate electrode 301, and the second resistor electrode 402 is electrically connected to the gate supply electrode 302, so that the first odd-mode resistor 41 is provided between the gate electrode 301 and the gate supply electrode 302. Thus, energy of an odd-mode signal is consumed by the first odd-mode resistor 41, that is, odd-mode oscillation is suppressed, thereby improving stability of the semiconductor device.

It should be noted that the first resistor electrode 401 may be located at an end position of the gate electrode 301 close to the gate supply electrode 302, and the second resistor electrode 402 may be located at an end position of the gate supply electrode 302 close to the gate electrode 301, so that the degree of freedom in providing the first odd-mode resistor 40 can be improved.

It may be understood that the electrode structure 30 may further include a source electrode 305 and a source supply electrode electrically connected to the source electrode 305, and the electrode structure 30 may further include a drain electrode structure 32. The drain electrode structure 32 includes a drain electrode 303 and a drain supply electrode 304 electrically connected to the drain electrode 303. The source electrode 305 may serve as an input terminal of the semiconductor device, and the drain electrode 303 may serve as an output terminal of the semiconductor device. The drain supply electrode 304 may be understood as a drain pad. The drain electrode 303 in the first active region aa1 may be connected to the drain supply electrode 304 located in the passive region bb. The drain electrode 303 may receive a voltage signal through the drain supply electrode 304, so as to ensure normal operation of the semiconductor device.

In the semiconductor device provided in the embodiments of the present disclosure, the first odd-mode resistor 41 includes the first resistor electrode 401 and the second resistor electrode 402. The first resistor electrode 401 and the second resistor electrode 402 both form ohmic contact with the two-dimensional electron gas, and the two-dimensional-electron-gas conductive channel exists between the first resistor electrode 401 and the second resistor electrode 402, so that the first resistor electrode 401 and the second resistor electrode 402 can be channel-conducted to implement electrical connection. Further, for the gate electrode 301 and the gate supply electrode 302 that are spaced apart from each other, in a same first odd-mode resistor 41, the first resistor electrode 401 is electrically connected to the at least one gate electrode 301, and the second resistor electrode 402 is electrically connected to the gate supply electrode 302, so that the first odd-mode resistor 41 can dissipate an odd-mode signal in the gate electrode 301, thereby suppressing generation of odd-mode oscillation and further improving stability of the semiconductor device.

Optionally, with continued reference to FIG. 1, in a case that the at least one gate electrode 301 includes a plurality of gate electrodes 301, any gate electrode 301 is spaced apart from the gate supply electrode 302, and a first odd-mode resistor 41 is provided between any gate electrode 301 and the gate supply electrode 302.

Specifically, the first resistor electrode 401 is provided at an end position of each gate electrode 301 close to the gate supply electrode 302, at least two second resistor electrodes 402 are provided at positions of the gate supply electrode 302 close to the gate electrode 301, and the first resistor electrode 401 and the second resistor electrode 402 are provided correspondingly. That is, the number of first odd-mode resistors 41 is the same as the number of gate electrodes 301, so that odd-mode oscillation can be further suppressed by the first odd-mode resistors 41, thereby improving stability of the semiconductor device.

Optionally, with continued reference to FIG. 1, in a case that the at least one gate electrode 301 includes a plurality of gate electrodes 301, each gate electrode 301 of the plurality of gate electrodes 301 extends along a first direction (for example, the direction Y shown in FIG. 1), and the plurality of gate electrodes 301 are arranged along a second direction (for example, the direction X shown in FIG. 1). Along the second direction X, any two adjacent gate electrodes 301 are symmetrically disposed about a symmetry axis (for example, the vertical long dashed line M shown in FIG. 1), and the symmetry axis M extends along the first direction Y. The first direction Y and the second direction X intersect and are both parallel to a plane in which the substrate 10 is located. The first odd-mode resistors 41 electrically connected to the two symmetrically disposed gate electrodes 301 are also symmetrically disposed about the symmetry axis M.

Specifically, the first odd-mode resistors 41 electrically connected to the two symmetrically disposed gate electrodes 301 are symmetrically disposed about the symmetry axis M, so that phase balance of each gate electrode 301 can be ensured and odd-mode oscillation is less likely to occur. In addition, the symmetry of the two first odd-mode resistors 41 is consistent with the symmetry of the two gate electrodes 301, so that the possibility of odd-mode signal oscillation being generated in the semiconductor device can be further reduced, and stability of radio-frequency signals can also be ensured.

Optionally, as shown in FIG. 3, in a case that the at least one gate electrode 301 includes a plurality of gate electrodes 301, each gate electrode 301 of the plurality of gate electrodes 301 extends along the first direction Y, and the plurality of gate electrodes 301 are arranged along the second direction X. The first direction Y and the second direction X intersect and are both parallel to a plane in which the substrate 10 is located. For the gate electrode 301 and the gate supply electrode 302 that are spaced apart from each other, in a same first odd-mode resistor 41, the first resistor electrode 401 is electrically connected to at least two gate electrodes 301 sequentially arranged along the second direction X, and the second resistor electrode 402 is electrically connected to the gate supply electrode 302.

Specifically, in a same first odd-mode resistor 41, the first resistor electrode 401 is electrically connected to the at least two gate electrodes 301 sequentially arranged along the second direction X. That is, the at least two sequentially arranged gate electrodes 301 share a same first resistor electrode 401, namely, the at least two gate electrodes 301 are connected to the gate supply electrode 302 through a same first odd-mode resistor 41. In this way, on the one hand, odd-mode signals in each gate electrode 301 can be suppressed, thereby facilitating phase balance of each gate electrode 301; on the other hand, a resistance value of the first odd-mode resistor 41 can be increased and an area of the semiconductor device can be saved, thereby implementing miniaturized design of the semiconductor device. Preferably, the two adjacently disposed gate electrodes 301 are gate electrodes 301 on two sides of a same drain electrode 303.

It may be understood that FIG. 3 merely shows a technical solution in which the first resistor electrode 401 in a same first odd-mode resistor 41 is electrically connected to two gate electrodes 301 sequentially arranged along the second direction. For example, three or more gate electrodes 301 may share a same first resistor electrode 401.

Further, each gate electrode 301 of the plurality of gate electrodes 301 extends along the first direction Y, the plurality of gate electrodes 301 are arranged along the second direction X, and any two adjacent gate electrodes 301 along the second direction X are symmetrically disposed about a symmetry axis (for example, the vertical long dashed line M shown in FIG. 3). The symmetry axis M extends along the first direction Y. The first direction Y and the second direction X intersect and are both parallel to a plane in which the substrate 10 is located. Two first odd-mode resistors 41 electrically connected to the two symmetrically disposed gate electrodes 301 are also symmetrically disposed about the symmetry axis M.

Optionally, as shown in FIG. 4, the electrode structure 30 further includes a source electrode 305. Along the second direction X, the source electrode 305 is located between two adjacently disposed gate electrodes 301. In a same first odd-mode resistor 41, the first resistor electrode 401 is electrically connected to the two gate electrodes 301 adjacently disposed with the source electrode 305, and the second resistor electrode 402 is electrically connected to the gate supply electrode 302.

Specifically, in a same first odd-mode resistor 41, the first resistor electrode 401 is electrically connected to the two gate electrodes 301 adjacently disposed with the source electrode 305, and the second resistor electrode 402 is electrically connected to the gate supply electrode 302. That is, along the second direction X, the gate electrodes 301 respectively located on two sides of the source electrode 305 are electrically connected to a same first resistor electrode 401, and the second resistor electrode 402 is provided corresponding to the first resistor electrode 401.

With continued reference to FIG. 3, in a same first odd-mode resistor 41, the first resistor electrode 401 is electrically connected to two gate electrodes 301 adjacently disposed with the drain electrode 303, and the second resistor electrode 402 is electrically connected to the gate supply electrode 302. That is, the two gate electrodes 301 on two sides of the drain electrode 303 are connected to a same first resistor electrode 401, so that diversity in the arrangement of the semiconductor device can be implemented.

Optionally, with continued reference to FIG. 1, the gate electrode 301 includes a gate main body portion 3011 and a gate tail portion 3012 that are connected. The gate tail portion 3012 is located on a side of the gate main body portion 3011 close to the gate supply electrode 302, and along the second direction X, an extension width of the gate tail portion 3012 is greater than an extension width of the gate main body portion 3011. The second direction X intersects an extension direction of the gate electrode 301. The first resistor electrode 401 is electrically connected to the gate tail portion 3012, and a portion of the two-dimensional electron gas is retained in the semiconductor structure at a position where the gate tail portion 3012 is connected to the first resistor electrode 401.

Specifically, along the second direction X, the extension width of the gate tail portion 3012 is greater than the extension width of the gate main body portion 3011, that is, along the second direction X, a width of the gate electrode 301 located in the passive region bb is greater than a width of the gate electrode 301 located in the first active region aa1, thereby helping to improve reliability. In addition, a curvature radius of the gate tail portion 3012 located in the passive region bb along the second direction X may be greater than a width of the gate main body portion 3011 located in the first active region aa1 along the second direction X, so that the difficulty of penetration of a developer solution from an end portion of the gate electrode 301 toward the middle can be reduced, thereby reducing development difficulty. Gate electrodes 301 corresponding to corner positions at two ends of the source electrode 305 or the drain electrode 303 may also be appropriately compensated, so as to compensate for or completely eliminate a problem that a width of the gate electrode 301 is reduced due to light diffraction. Further, the first resistor electrode 401 is electrically connected to the gate tail portion 3012, that is, the first resistor electrode 401 is electrically connected to a region of the gate electrode 301 having a relatively large width, so that connection stability is ensured on the one hand, and on the other hand the first resistor electrode 401 is facilitated to have relatively small contact resistance, thereby avoiding poor contact or relatively large signal loss between the gate electrode 301 and the first resistor electrode 401.

Further, a portion of the two-dimensional electron gas below the gate tail portion 3012 located in the passive region bb is retained, and the gate tail portion 3012 has zero contact with the two-dimensional electron gas, so as to ensure that the first resistor electrode 401 forms ohmic contact with the two-dimensional electron gas and is also electrically connected to the gate tail portion 3012, and to avoid contact between the gate tail portion 3012 and the two-dimensional electron gas.

Optionally, with continued reference to FIG. 1, the gate supply electrode 302 includes a supply body portion 3021 and at least one supply protruding portion 3022. The supply body portion 3021 and the at least one supply protruding portion 3022 are connected to each other. The at least one supply protruding portion 3022 is located on a side of the supply body portion 3021 close to the gate electrode 301. The second resistor electrode 402 is electrically connected to the supply protruding portion 3022.

Specifically, the supply protruding portion 3022 is located on the side of the supply body portion 3021 close to the gate electrode 301. The second resistor electrode 402 is electrically connected to the supply protruding portion 3022, and the supply body portion 3021 serves as a main supply pad, so that operating characteristics of the gate supply electrode 302 are not affected. In addition, adjusting a shape of the supply protruding portion 3022 can ensure a contact effect between the gate supply electrode 302 and the second resistor electrode 402, thereby helping to ensure contact stability between the gate supply electrode 302 and the second resistor electrode 402. Adjusting a length of the supply protruding portion 3022 can adjust a distance between the first resistor electrode 401 and the second resistor electrode 402, so as to facilitate adjustment of a resistance value of the first odd-mode resistor 41, thereby making the resistance value of the first odd-mode resistor 41 adjustable in a simple adjustment manner and further satisfying requirements in various different scenarios.

Optionally, with continued reference to FIG. 1, in a same first odd-mode resistor 41, the first resistor electrode 401 and the second resistor electrode 402 are arranged along the first direction Y and extend along the second direction X. The first direction Y and the second direction X intersect and are both parallel to a plane in which the substrate 10 is located, and the first direction Y is parallel to an extension direction of the gate electrode 301.

Specifically, because an odd-mode signal existing in the gate electrode 301 affects stability of the semiconductor device, an arrangement direction of the first resistor electrode 401 and the second resistor electrode 402 is set to be the same as the extension direction of the gate electrode 301, so that the odd-mode signal in the gate electrode 301 can be dissipated by the first odd-mode resistor 41, thereby suppressing odd-mode oscillation and further ensuring stability of the semiconductor device.

Optionally, with continued reference to FIG. 1, in a same first odd-mode resistor 41, a distance between the first resistor electrode 401 and the second resistor electrode 402 is d, extension lengths of the first resistor electrode 401 and the second resistor electrode 402 are both w, a contact resistance of the first resistor electrode 401 is Rc1, a contact resistance of the second resistor electrode 402 is Rc2, a sheet resistance of the two-dimensional electron gas between the first resistor electrode 401 and the second resistor electrode 402 is Rsh, and a resistance value of the first odd-mode resistor 41 is R=Rc1+Rc2+Rsh·d/W.

Optionally, with continued reference to FIGS. 1 and 2, the electrode structure 30 may further include an ohmic electrode and a Schottky electrode. The ohmic electrode includes the source electrode 305 and/or the drain electrode 303, and the Schottky electrode includes the gate electrode 301. It may be understood that the ohmic electrode forms ohmic contact with the epitaxial structure 20, and the Schottky electrode forms Schottky contact with the epitaxial structure 20.

The first resistor electrode 401 and the second resistor electrode 402 are both disposed in the same layer as the ohmic electrode. The gate electrode 301 covers and contacts the first resistor electrode 401 to implement electrical connection, and the second resistor electrode 402 contacts the gate supply electrode 302 to implement electrical connection, thereby ensuring that the first odd-mode resistor 41 forms ohmic contact with the two-dimensional electron gas and suppresses an odd-mode signal during signal transmission of each gate electrode 301.

Specifically, this embodiment is described by taking the drain electrode 303 as an example of the ohmic electrode. The first resistor electrode 401 and the second resistor electrode 402 are both disposed in the same layer as the drain electrode 303, that is, the first resistor electrode 401, the second resistor electrode 402, and the drain electrode 303 are manufactured by using a same mask process. In other words, the resistor electrodes in the first odd-mode resistor 41 are all provided in an ohmic contact metal layer, that is, the first resistor electrode 401, the second resistor electrode 402, and the drain electrode 303 are disposed in the same layer, so that, on the one hand, good ohmic contact between the resistor electrode and the two-dimensional electron gas can be ensured and a thinned arrangement of the semiconductor device can also be implemented, and on the other hand, a process flow can be simplified.

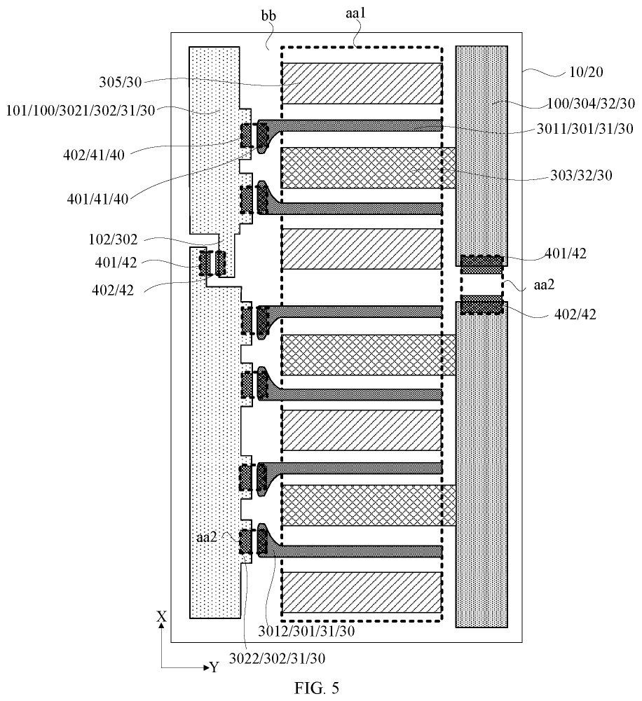

Optionally, as shown in FIG. 5, the electrode structure 30 further includes an ohmic electrode structure. For example, the ohmic electrode structure may be the drain electrode structure 32, and the drain electrode structure 32 includes a drain electrode 303 and a drain supply electrode 304 that are connected to each other. The gate supply electrode 302 includes at least two supply sub-portions 100 that are spaced apart from each other, and the drain supply electrode 304 includes at least two supply sub-portions 100 that are spaced apart from each other. The at least one odd-mode resistor 40 further includes at least one second odd-mode resistor 42. Each second odd-mode resistor 42 includes a first resistor electrode 401 and a second resistor electrode 402. In a same second odd-mode resistor 42, the first resistor electrode 401 and the second resistor electrode 402 both form ohmic contact with the two-dimensional electron gas, and along an arrangement direction of the first resistor electrode 401 and the second resistor electrode 402, a two-dimensional-electron-gas conductive channel exists between the first resistor electrode 401 and the second resistor electrode 402. In a same second odd-mode resistor 42, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100.

Specifically, the gate supply electrode 302 includes at least two supply sub-portions 100 that are spaced apart from each other, the drain supply electrode 304 includes at least two supply sub-portions 100 that are spaced apart from each other, and two adjacent supply sub-portions 100 are spaced apart from each other. That is, the gate supply electrode 302 is not an integral whole, but is arranged in a disconnected manner, and the drain supply electrode 304 is not an integral whole, but is arranged in a disconnected manner, so that the semiconductor device can be divided into at least two cell units, and isolation between two adjacent cell units can be increased by increasing a disconnection spacing between two adjacent supply sub-portions 100.

As one feasible implementation, the gate supply electrode 302 includes at least two supply sub-portions 100 that are spaced apart from each other. In a same second odd-mode resistor 42, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100. The first resistor electrode 401 and the second resistor electrode 402 both form ohmic contact with the two-dimensional electron gas. The second odd-mode resistor 42 is provided in a region of the passive region bb where the two-dimensional electron gas is retained, namely, the two-dimensional electron gas in the region of the passive region bb where the second odd-mode resistor 42 is provided is retained, so that the second odd-mode resistor 42 forms ohmic contact with the two-dimensional electron gas. In addition, along an arrangement direction of the first resistor electrode 401 and the second resistor electrode 402, a two-dimensional-electron-gas conductive channel exists between the first resistor electrode 401 and the second resistor electrode 402, that is, the first resistor electrode 401 and the second resistor electrode 402 are channel-conducted. Further, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100, so that electrical connection between the two adjacent supply sub-portions 100 can be implemented through the first resistor electrode 401 and the second resistor electrode 402. In other words, a second odd-mode resistor 42 is provided between the two adjacent supply sub-portions 100, so that the second odd-mode resistor 42 consumes energy of an odd-mode signal, that is, odd-mode oscillation in a feedback loop formed by the gate electrode 301 and the drain electrode 303 can be further suppressed, thereby improving stability of the semiconductor device.

As another feasible implementation, the drain supply electrode 303 includes at least two supply sub-portions 100 that are spaced apart from each other. In a same second odd-mode resistor 42, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100, so that electrical connection between the two adjacent supply sub-portions 100 can be implemented through the first resistor electrode 401 and the second resistor electrode 402. In other words, a second odd-mode resistor 42 is provided between the two adjacent supply sub-portions 100, so that the second odd-mode resistor 42 consumes energy of an odd-mode signal, that is, odd-mode oscillation in a feedback loop formed by the gate electrode 301 and the drain electrode 303 can be further suppressed, thereby improving stability of the semiconductor device.

It may be understood that FIG. 5 shows that the gate supply electrode 302 includes two supply sub-portions 100 that are spaced apart from each other, and the supply sub-portion 100 includes a supply main body portion 101 and at least one supply interdigital portion 102 electrically connected to the supply main body portion 101. Along the second direction X, the at least one supply interdigital portion 102 is located on a side of the supply main body portion 101, and each supply interdigital portion 102 of the at least one supply interdigital portion 102 extends along the second direction X. The at least one supply interdigital portion 102 of one supply sub-portion 100 of two supply sub-portions 100 adjacently disposed along the second direction X and the at least one supply interdigital portion 102 of the other supply sub-portion 100 of the two supply sub-portions 100 adjacently disposed along the second direction X are alternately arranged along the first direction Y. The first direction Y is parallel to a plane in which the substrate 10 is located and intersects the second direction X. For example, the number of supply interdigital portions 102 may be at least two, so that at least two second odd-mode resistors 42 can be connected in parallel, thereby implementing diversity of a resistance value of the second odd-mode resistors 42 to achieve different suppression effects and further satisfy requirements in various different scenarios.

As still another feasible implementation, the gate supply electrode 302 and the drain supply electrode 304 each include at least two supply sub-portions 100 that are spaced apart from each other. That is, a second odd-mode resistor 42 is provided between the supply sub-portions 100 of the drain supply electrode 304, and a second odd-mode resistor 42 is provided between the supply sub-portions 100 of the gate supply electrode 302, so that, on the one hand, odd-mode oscillation in a feedback loop formed by the gate electrode 301 and the drain electrode 303 can be further suppressed to improve stability of the semiconductor device, and on the other hand, diversified arrangement of the semiconductor device can be implemented.

The above describes a semiconductor device based on the first embodiment. Another semiconductor device is described below based on a second embodiment. The second embodiment is described from the perspective that the at least one odd-mode resistor 40 includes only at least one second odd-mode resistor 42. As shown in FIGS. 6 to 9, a structure of the semiconductor device is specifically as follows.

The electrode structure 30 includes at least one electrode 300-1 and at least one supply electrode 300-2 electrically connected to the at least one electrode 300-1. Each supply electrode 300-2 of the at least one supply electrode 300-2 includes at least two supply sub-portions 100, and any two adjacent supply sub-portions 100 are spaced apart from each other. Each second odd-mode resistor 42 of the at least one second odd-mode resistor 42 includes a first resistor electrode 401 and a second resistor electrode 402. In a same second odd-mode resistor 42, the first resistor electrode 401 and the second resistor electrode 402 both form ohmic contact with the two-dimensional electron gas, and along an arrangement direction of the first resistor electrode 401 and the second resistor electrode 402, a two-dimensional-electron-gas conductive channel exists between the first resistor electrode 401 and the second resistor electrode 402. In a same second odd-mode resistor 42, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100.

Specifically, the electrode structure 30 may include a source electrode structure 33, a gate electrode structure 31, and a drain electrode structure 32. The source electrode structure 33 may include a source electrode 305. The gate electrode structure 31 may include a gate electrode 301 and a gate supply electrode 302 connected to the gate electrode 301. The drain electrode structure 32 may include a drain electrode 303 and a drain supply electrode 304 electrically connected to the drain electrode 303. The source electrode 305 may serve as an input terminal of the semiconductor device, and the drain electrode 303 may serve as an output terminal of the semiconductor device. The drain supply electrode 304 may be understood as a drain pad. The drain electrode 303 in the first active region aa1 may be connected to the drain supply electrode 304 located in the passive region bb. The gate electrode structure 31 may include the gate electrode 301 located in the first active region aa1 and the gate supply electrode 302 located in the passive region bb. The gate supply electrode 302 is a gate pad, is connected to the gate electrode 301 in the first active region aa1, and provides a gate voltage signal to the gate electrode 301, so as to ensure normal operation of the semiconductor device. The electrode 300 of the semiconductor device of the present disclosure may include an ohmic electrode and a Schottky electrode. The ohmic electrode includes the source electrode 305 and/or the drain electrode 303, and the Schottky electrode includes the gate electrode 301. It may be understood that the ohmic electrode forms ohmic contact with the epitaxial structure 20, and the Schottky electrode forms Schottky contact with the epitaxial structure 20.

Further, the at least one electrode 300-1 may include the gate electrode 301 and/or the drain electrode 303, and the at least one supply electrode 300-2 may include the gate supply electrode 302 electrically connected to the gate electrode 301 and/or the drain supply electrode 304 electrically connected to the drain electrode 303.

Specifically, each supply electrode 300-2 of the at least one supply electrode 300-2 includes at least two supply sub-portions 100, and two adjacent supply sub-portions 100 are spaced apart from each other. That is, each supply electrode 300-2 is not an integral whole, but is arranged in a disconnected manner, so that the semiconductor device can be divided into at least two cell units 800, and increasing a disconnection spacing between two adjacent supply sub-portions 100 can increase isolation between two adjacent cell units 800. Further, the second odd-mode resistor 42 is provided in a region of the passive region bb where the two-dimensional electron gas is retained, namely, the two-dimensional electron gas in the region of the passive region bb where the second odd-mode resistor 42 is provided is retained, so that the second odd-mode resistor 42 forms ohmic contact with the two-dimensional electron gas. The supply electrode 300-2 has zero contact with the two-dimensional electron gas in the region where the second odd-mode resistor 42 is located. That is, when the supply electrode 300-2 is manufactured, the supply electrode 300-2 cannot completely wrap the first resistor electrode 401 and the second resistor electrode 402 of the s econd odd-mode resistor 42, but at least exposes a side surface of the first resistor electrode 401 of the second odd-mode resistor 42 and a side surface of the second resistor electrode 402 of the second odd-mode resistor 42, the two side surfaces being adjacent to each other, so as to ensure that the first resistor electrode 401 and the second resistor electrode 402 of the second odd-mode resistor 42 form complete contact with the two-dimensional electron gas, and to avoid contact between the supply electrode 300-2 and the two-dimensional electron gas. In addition, along an arrangement direction of the first resistor electrode 401 and the second resistor electrode 402 of the second odd-mode resistor 42, a two-dimensional-electron-gas conductive channel exists between the first resistor electrode 401 and the second resistor electrode 402 of the second odd-mode resistor 42, that is, the first resistor electrode 401 and the second resistor electrode 402 of the second odd-mode resistor 42 are channel-conducted, and are electrically connected by the two-dimensional electron gas. Further, a second odd-mode resistor 42 is provided between two adjacent supply sub-portions 100, the first resistor electrode 401 of the second odd-mode resistor 42 is electrically connected to one supply sub-portion 100 of the two adjacent supply sub-portions 100, and the second resistor electrode 402 of the second odd-mode resistor 42 is electrically connected t o the other supply sub-portion 100 of the two adjacent supply sub-portions 100, so that electrical connection between the two adjacent supply sub-portions 100 can be implemented through the first resistor electrode 401 and the second resistor electrode 402. In other words, a second odd-mode resistor 42 is provided between two adjacent supply sub-portions 100, so that the second odd-mode resistor 42 consumes energy of an odd-mode signal, that is, odd-mode oscillation in a feedback loop formed by the gate electrode 301 and the drain electrode 303 can be suppressed, thereby improving stability of the semiconductor device.

In the semiconductor device provided in the embodiments of the present disclosure, the supply sub-portions 100 of the supply electrode 300-2 are spaced apart from each other, that is, the supply electrode 300-2 is disconnected to form different supply sub-portions 100, so that, on the one hand, the semiconductor device can be divided into at least two cell units 800, and on the other hand, a spacing between the supply sub-portions 100 can be increased, thereby increasing isolation of each cell unit 800. Further, in a same second odd-mode resistor 42, the first resistor electrode 401 is electrically connected to one supply sub-portion 100 of two adjacent supply sub-portions 100, and the second resistor electrode 402 is electrically connected to the other supply sub-portion 100 of the two adjacent supply sub-portions 100. That is, a second odd-mode resistor 42 is provided between the two adjacent supply sub-portions 100, so that energy of an odd-mode signal can be dissipated by the second odd-mode resistor 42 to suppress generation of odd-mode oscillation, thereby reducing parasitic capacitance caused by the supply electrode 300-2 and further improving stability of the semiconductor device.

Optionally, with continued reference to FIG. 6, the electrode structure 30 includes a gate electrode structure 31 and a drain electrode structure 32. The gate electrode structure 31 includes a gate electrode 301 and a gate supply electrode 302 electrically connected to the gate electrode 301, and the drain electrode structure 32 includes a drain electrode 303 and a drain supply electrode 304 electrically connected to the drain electrode 303. The gate supply electrode 302 includes at least two gate supply sub-portions 100-1, two adjacent gate supply sub-portions 100-1 are spaced apart from each other, and in a same second odd-mode resistor 42, the first resistor electrode 401 is electrically connected to one gate supply sub-portion 100-1 of two adjacent gate supply sub-portions 100-1, and the second resistor electrode 402 is electrically connected to the other gate supply sub-portion 100-1 of the two adjacent gate supply sub-portions 100-1; and/or the drain supply electrode 304 includes at least two drain supply sub-portions 100-2, two adjacent drain supply sub-portions 100-2 are spaced apart from each other, and in a same second odd-mode resistor 42, the first resistor electrode 401 is electrically connected to one drain supply sub-portion 100-2 of two adjacent drain supply sub-portions 100-2, and the second resistor electrode 402 is electrically connected to the other drain supply sub-portion 100-2 of the two adjacent drain supply sub-portions 100-2.

Specifically, with continued reference to FIG. 6, as one feasible implementation, in a same second odd-mode resistor 42, the first resistor electrode 401 is electrically connected to one gate supply sub-portion 100-1 of two adjacent gate supply sub-portions 100-1, and the second resistor electrode 402 is electrically connected to the other gate supply sub-portion 100-1 of the two adjacent gate supply sub-portions 100-1. The second odd-mode resistor 42 forms ohmic contact with the two-dimensional electron gas, and the first resistor electrode 401 and the second resistor electrode 402 of the second odd-mode resistor 42 are respectively electrically connected to the two adjacent gate supply sub-portions 100-1. That is, the first resistor electrode 401 and the second resistor electrode 402 are electrically connected through the two-dimensional electron gas, so that odd-mode oscillation can be suppressed by providing the second odd-mode resistor 42, thereby improving stability of the semiconductor device.

As another feasible implementation, with continued reference to FIG. 6, in a same second odd-mode resistor 42, the first resistor electrode 401 is electrically connected to one drain supply sub-portion 100-2 of two adjacent drain supply sub-portions 100-2, and the second resistor electrode 402 is electrically connected to the other drain supply sub-portion 100-2 of the two adjacent drain supply sub-portions 100-2. The second odd-mode resistor 42 forms ohmic contact with the two-dimensional electron gas, and the first resistor electrode 401 and the second resistor electrode 402 of the second odd-mode resistor 42 are respectively electrically connected to the two adjacent drain supply sub-portions 100-2. That is, the first resistor electrode 401 and the second resistor electrode 402 are electrically connected through the two-dimensional electron gas, so that odd-mode oscillation can be suppressed by providing the second odd-mode resistor 42, thereby improving stability of the semiconductor device.

As still another feasible implementation, with continued reference to FIG. 6, providing a second odd-mode resistor 42 between the gate supply sub-portions 100-1 and a second odd-mode resistor 42 between the drain supply sub-portions 100-2 can further suppress odd-mode oscillation in a feedback loop formed by the gate electrode 301 and the drain electrode 303, thereby further improving stability of the semiconductor device.

Optionally, with continued reference to FIGS. 7 and 8, the electrode 300-1 includes an ohmic electrode, and the first resistor electrode 401 and the second resistor electrode 402 of the second odd-mode resistor 42 are both disposed in the same layer as the ohmic electrode. The ohmic electrode includes the drain electrode 303 and/or the source electrode 305. In the second odd-mode resistor 42 located between the gate supply sub-portions 100-1, the first resistor electrode 401 and the second resistor electrode 402 are both disposed in the same layer as the ohmic electrode, for example, in the same layer as the drain electrode 303 or the source electrode 305, so that it can be ensured that the second odd-mode resistor 42 located between the gate supply sub-portions 100-1 forms ohmic contact with the two-dimensional electron gas. In the second odd-mode resistor 42 located between the drain supply sub-portions 100-2, the first resistor electrode 401 and the second resistor electrode 402 are both disposed in the same layer as the ohmic electrode, for example, in the same layer as the drain electrode 303 or the source electrode 305, so that it can be ensured that the second odd-mode resistor 42 located between the drain supply sub-portions 100-2 forms ohmic contact with the two-dimensional electron gas.

Specifically, this embodiment is described by taking the drain electrode 303 as an example of the ohmic electrode. In the second odd-mode resistor 42 located between the gate supply sub-portions 100-1, the first resistor electrode 401 and the second resistor electrode 402 are both disposed in the same layer as the drain electrode 303, and in the second odd-mode resistor 42 located between the drain supply sub-portions 100-2, the first resistor electrode 401 and the second resistor electrode 402 are both disposed in the same layer as the drain electrode 303. That is, the resistor electrodes in the second odd-mode resistor 42 are all provided in an ohmic contact metal layer, so that the first resistor electrode 401, the second resistor electrode 402, and any one of the drain electrode 303 or the source electrode 305 can be simultaneously manufactured on a side of the epitaxial structure 20 away from the substrate 10 by using a same mask process, and no new process flow needs to be added to manufacture two resistor electrodes in the second odd-mode resistor 42. In other words, a manufacturing process of the second odd-mode resistor 42 is compatible with a process flow of a semiconductor chip, and therefore the process is simple. In addition, the first resistor electrode 401 and the second resistor electrode 402 are disposed in the same layer as the ohmic electrode of the semiconductor device and by a same process; therefore, good ohmic contact between the resistor electrode and the two-dimensional electron gas can be ensured, and a thinned arrangement of the semiconductor device can also be implemented.

Further, the second odd-mode resistor 42 forms ohmic contact with the two-dimensional electron gas and is internally electrically connected by the two-dimensional electron gas, and the second odd-mode resistor 42 contacts the drain supply electrode 304 and the gate supply electrode 302 to implement electrical connection, so that odd-mode oscillation can be suppressed and stability of the semiconductor device can be improved.

Optionally, with continued reference to FIG. 6, at least two supply sub-portions 100 in a same supply electrode 300-2 are arranged along the second direction (for example, the direction X shown in FIG. 6). The second direction X is parallel to a plane in which the substrate 10 is located. The supply sub-portion 100 includes a supply main body portion 101, and the supply main body portions 101 of two supply sub-portions 100 adjacently disposed along the second direction X are arranged along the second direction X. In a same second odd-mode resistor 42, the first resistor electrode 401 and the second resistor electrode 402 are arranged along the second direction X and extend along the first direction (for example, the direction Y shown in FIG. 6). In a same second odd-mode resistor 42, the first resistor electrode 401 is electrically connected to one supply main body portion 101 of two supply main body portions 101 adjacently disposed along the second direction X, and the second resistor electrode 402 is electrically connected to the other supply main body portion 101 of the two supply main body portions 101 adjacently disposed along the second direction X. The first direction Y is parallel to a plane in which the substrate 10 is located and intersects the second direction X.

Specifically, with continued reference to FIG. 6, the gate supply sub-portions 100-1 and the second odd-mode resistor 42 located between the gate supply sub-portions 100-1 are taken as an example. At least two gate supply sub-portions 100-1 of the gate supply electrode 302 are arranged along the second direction X. In a same second odd-mode resistor 42, the first resistor electrode 401 and the second resistor electrode 402 are arranged along the second direction X and extend along the first direction Y. In a same second odd-mode resistor 42, the first resistor electrode 401 is electrically connected to the supply main body portion 101 of a gate supply sub-portion 100-1, and the second resistor electrode 402 is electrically connected to the supply main body portion 101 of another adjacently disposed gate supply sub-portion 100-1, so that odd-mode oscillation can be suppressed by providing the second odd-mode resistor 42, thereby improving stability of the semiconductor device.

Optionally, with continued reference to FIG. 6, at least two supply sub-portions 100 in a same supply electrode 300-2 are arranged along the second direction X. The second direction X is parallel to a plane in which the substrate 10 is located. The supply sub-portion 100 includes a supply main body portion 101 and at least one supply interdigital portion 102. The supply main body portion 101 and the at least one supply interdigital portion 102 are connected to each other. Along the second direction X, the supply interdigital portion 102 is located on a side of the supply main body portion 101, and the supply interdigital portion 102 extends along the second direction X. The at least one supply interdigital portion 102 of one supply sub-portion 100 of two supply sub-portions 100 adjacently disposed along the second direction X and the at least one supply interdigital portion 102 of the other supply sub-portion 100 of the two supply sub-portions 100 adjacently disposed along the second direction X are alternately arranged along the first direction Y. The first direction Y is parallel to a plane in which the substrate 10 is located and intersects the second direction X. In a same second odd-mode resistor 42, the first resistor electrode 401 and the second resistor electrode 402 extend along the second direction X and are arranged along the first direction Y. In a same second odd-mode resistor 42, the first resistor electrode 401 is electrically connected to one supply interdigital portion 102 of two supply interdigital portions 102 adjacently disposed along the first direction Y, and the second resistor electrode 402 is electrically connected to the other supply interdigital portion 102 of the two supply interdigital portions 102 adjacently disposed along the first direction Y.

Specifically, with continued reference to FIG. 6, the drain supply sub-portions 100-2 and the second odd-mode resistor 42 located between the drain supply sub-portions 100-2 are taken as an example. The drain supply sub-portion 100-2 includes a supply main body portion 101 and at least one supply interdigital portion 102. In a same second odd-mode resistor 42, the first resistor electrode 401 and the second resistor electrode 402 extend along the second direction X and are arranged along the first direction Y. In a same second odd-mode resistor 42, the first resistor electrode 401 is electrically connected to one supply interdigital portion 102 of two supply interdigital portions 102 adjacently disposed along the first direction Y, and the second resistor electrode 402 is electrically connected to the other supply interdigital portion 102 of the two supply interdigital portions 102 adjacently disposed along the first direction Y, so that, on the one hand, diversified arrangement of the semiconductor device can be implemented, and on the other hand, providing the second odd-mode resistor 42 can suppress odd-mode oscillation, thereby improving stability of the semiconductor device.

For example, each drain supply sub-portion 100-2 shown in FIG. 6 includes only one supply interdigital portion 102. It may be understood that each drain supply sub-portion 100-2 may also include at least two supply interdigital portions 102, and the at least two supply interdigital portions 102 form a structure similar to a “comb-like structure”. The embodiments of the present disclosure do not specifically limit the number of supply interdigital portions 102 included in each supply sub-portion 100.

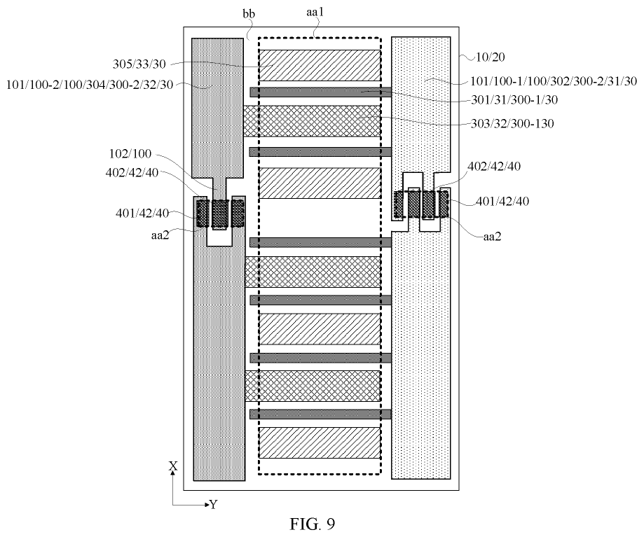

Optionally, as shown in FIG. 9, two supply sub-portions 100 adjacently disposed along the second direction X each include at least two supply interdigital portions 102. One supply interdigital portion 102 of any two supply interdigital portions 102 adjacently disposed along the first direction Y is electrically connected to the first resistor electrode 401, and the other supply interdigital portion 102 of the any two supply interdigital portions 102 adjacently disposed along the first direction Y is electrically connected to the second resistor electrode 402. The at least one second odd-mode resistor 42 includes at least two second odd-mode resistors 42, and the at least two second odd-mode resistors 42 are connected in parallel.

Specifically, the drain supply sub-portions 100-2 in FIG. 9 and the second odd-mode resistors 42 located between the drain supply sub-portions 100-2 are taken as an example. Two drain supply sub-portions 100-2 adjacently disposed along the second direction X include a total of three supply interdigital portions 102 arranged along the first direction Y, and each supply interdigital portion 102 is electrically connected to one resistor electrode. For example, along the first direction Y, an arrangement manner of the second odd-mode resistors 42 may be “first resistor electrode 401—second resistor electrode 402—first resistor electrode 401”. That is, the three supply interdigital portions 102 correspond to two second odd-mode resistors 42, and the two second odd-mode resistors 42 are connected in parallel through the second resistor electrode 402.

Specifically, the gate supply sub-portions 100-1 in FIG. 9 and the second odd-mode resistors 42 located between the gate supply sub-portions 100-1 are taken as an example. Two gate supply sub-portions 100-1 adjacently disposed along the second direction X include a total of four supply interdigital portions 102 arranged along the first direction Y, and each supply interdigital portion 102 is electrically connected to one resistor electrode. For example, along the first direction Y, an arrangement manner of the second odd-mode resistors 42 may be “first resistor electrode 401—second resistor electrode 402—first resistor electrode 401—second resistor electrode 402”. That is, the four supply interdigital portions 102 correspond to three second odd-mode resistors 42, and the three second odd-mode resistors 42 are connected in parallel.

It should be noted that FIG. 9 merely exemplarily shows a technical solution in which two second odd-mode resistors 42 or three second odd-mode resistors 42 are connected in parallel. It may be understood that the number of second odd-mode resistors 42 may also be greater than or equal to four. The embodiments of the present disclosure do not specifically limit the number of second odd-mode resistors 42. By connecting at least two second odd-mode resistors 42 in parallel, diversity of a resistance value of the second odd-mode resistor 42 can be further implemented, so as to achieve different suppression effects and thereby satisfy requirements in various different scenarios.

Optionally, with continued reference to FIGS. 6 and 7, in a same second odd-mode resistor 42, a distance between the first resistor electrode 401 and the second resistor electrode 402 is d, extension lengths of the first resistor electrode 401 and the second resistor electrode 402 are both w, a contact resistance of the first resistor electrode 401 is Rc1, a contact resistance of the second resistor electrode 402 is Rc2, a sheet resistance of the two-dimensional electron gas between the first resistor electrode 401 and the second resistor electrode 402 is Rsh, and a resistance value of the second odd-mode resistor 42 is R=Rc1+Rc2+Rsh·d/W.

It may be understood that, compared with a thin-film resistor in the related art, the second odd-mode resistor 42 provided in the embodiments of the present disclosure is disposed in the same layer as the drain electrode 303, and electrical connection and ohmic contact in the second odd-mode resistor 42 are implemented by the two-dimensional electron gas. Therefore, no new film layer needs to be added, material cost is reduced, a process flow is simplified, and the solution is suitable for large-scale commercial application.

The above describes another semiconductor device based on the second embodiment. The following describes commonalities between the semiconductor device based on the first embodiment and the another semiconductor device based on the second embodiment. As shown in FIGS. 5, 6, and 9, the semiconductor device further includes at least two cell units 800, each cell unit 800 includes a supply electrode sub-portion, and a second odd-mode resistor 42 is provided between two adjacent cell units 800.

Specifically, the supply electrode sub-portion may be understood as the gate supply electrode 302 or the drain supply electrode 304 in the cell unit 800. That is, each cell unit 800 includes a drain supply electrode 304 electrically connected to the drain electrode 303 and a gate supply electrode 302 electrically connected to the gate electrode 301. FIGS. 5, 6, and 9 merely show a technical solution in which the semiconductor device includes two cell units 800. It may be understood that the semiconductor device may also include more than two cell units 800, and a second odd-mode resistor 42 is provided between two adjacent cell units 800, so that odd-mode oscillation can be suppressed by providing the second odd-mode resistor 42, thereby improving stability of the semiconductor device.

It should be noted that the number of gate electrodes 301 included in each cell unit 800 may be the same or different. The embodiments of the present disclosure do not specifically limit the number of gate electrodes 301 included in each cell unit 800.

It should be understood that, from the perspective of semiconductor device design, the embodiments of the present disclosure can suppress odd-mode oscillation by providing the odd-mode resistor 40, thereby improving stability of the semiconductor device. The semiconductor device includes, but is not limited to, a high electron mobility transistor or another field effect transistor. The odd-mode resistor 40 provided in the semiconductor device according to the embodiments of the present disclosure can be widely used in manufacturing fields of semiconductor devices such as radio-frequency microwave and power electronics, and has more obvious advantages especially for gallium nitride electronic devices having a wide bandgap, high electron mobility, high breakdown field strength, and good thermal conductivity, so as to better satisfy high-performance requirements in rapidly developing fields such as electronic communications.

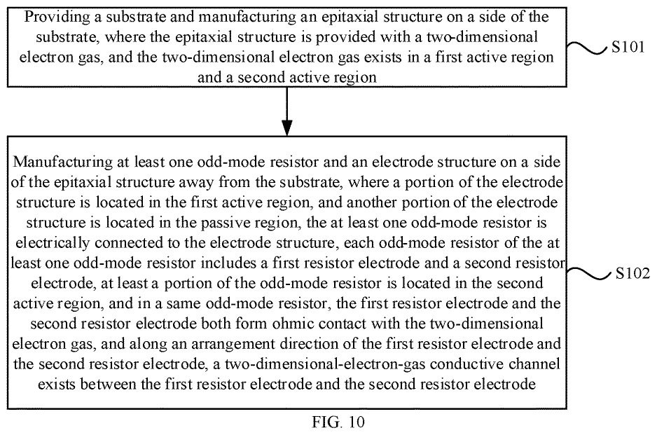

Based on the same inventive concept, embodiments of the present disclosure further provide a method for manufacturing a semiconductor device. The beneficial effects of the manufacturing method are the same as the beneficial effects of the semiconductor device described above. For parts not described in detail, reference may be made to the descriptions of the foregoing embodiments. FIG. 10 is a schematic flowchart of a method for manufacturing a semiconductor device according to an embodiment of the present disclosure. As shown in FIG. 10, the method for manufacturing the semiconductor device includes the following content.
S101, providing a substrate and manufacturing an epitaxial structure on a side of the substrate, where the epitaxial structure is provided with a two-dimensional electron gas, and the two-dimensional electron gas exists in a first active region and a second active region.

Specifically, a heterojunction structure is included between a channel layer and a barrier layer of the epitaxial structure, and the heterojunction structure may be the two-dimensional electron gas.
S102, manufacturing at least one odd-mode resistor and an electrode structure on a side of the epitaxial structure away from the substrate, where a portion of the electrode structure is located in the first active region, and another portion of the electrode structure is located in the passive region, the at least one odd-mode resistor is electrically connected to the electrode structure, each odd-mode resistor of the at least one odd-mode resistor includes a first resistor electrode and a second resistor electrode, at least a portion of the odd-mode resistor is located in the second active region, and in a same odd-mode resistor, the first resistor electrode and the second resistor electrode both form ohmic contact with the two-dimensional electron gas, and along an arrangement direction of the first resistor electrode and the second resistor electrode, a two-dimensional-electron-gas conductive channel exists between the first resistor electrode and the second resistor electrode.

Before the electrode structure is manufactured, the two-dimensional electron gas in the passive region is first eliminated, and the two-dimensional electron gas in a region where the odd-mode resistor is located (that is, the second active region) is also retained, so that the odd-mode resistor forms ohmic contact with the two-dimensional electron gas.

In the method for manufacturing a semiconductor device provided in the embodiments of the present disclosure, in a same odd-mode resistor, the first resistor electrode and the second resistor electrode are respectively electrically connected to the electrode structure, so that energy of an odd-mode signal can be dissipated by the odd-mode resistor, thereby suppressing generation of odd-mode oscillation and further improving stability of the semiconductor device.

Optionally, in a case that the at least one odd-mode resistor includes at least one first odd-mode resistor, the electrode structure includes a gate electrode structure and an ohmic electrode structure, the ohmic electrode structure includes an ohmic electrode, the gate electrode structure includes at least one gate electrode and a gate supply electrode, and each gate electrode of the at least one gate electrode is spaced apart from the gate supply electrode, the step S102 specifically includes: using a same mask process to manufacture, on the side of the epitaxial structure away from the substrate, the first resistor electrode and the second resistor electrode of each first odd-mode resistor of the at least one first odd-mode resistor and the ohmic electrode; manufacturing the at least one gate electrode in a region outside the ohmic electrode, where the at least one gate electrode contacts the first resistor electrode to implement electrical connection; and manufacturing the gate supply electrode, where the gate supply electrode contacts the second resistor electrode to implement electrical connection.

Optionally, in a case that the at least one odd-mode resistor includes at least one second odd-mode resistor, the electrode structure includes at least one electrode and at least one supply electrode electrically connected to the at least one electrode, each supply electrode of the at least one supply electrode includes at least two supply sub-portions, any two adjacent supply sub-portions of the at least two supply sub-portions are spaced apart from each other, and the at least one electrode includes an ohmic electrode, the step S102 specifically includes: using a same mask process to manufacture, on the side of the epitaxial structure away from the substrate, the first resistor electrode and the second resistor electrode of each second odd-mode resistor of the at least one second odd-mode resistor, and the ohmic electrode; and manufacturing the at least one supply electrode, where in a same second odd-mode resistor, the first resistor electrode contacts a supply sub-portion of the at least two supply sub-portions to implement electrical connection, and the second resistor electrode contacts another supply sub-portion of the at least two supply sub-portions to implement electrical connection.

It should be noted that the foregoing descriptions are merely preferred embodiments of the present disclosure and the technical principles applied thereto. A person skilled in the art would understand that the present disclosure is not limited to the specific embodiments described herein, and that various obvious changes, readjustments, and substitutions can be made by a person skilled in the art without departing from the protection scope of the present disclosure. Therefore, although the present disclosure has been described in relatively detail by means of the foregoing embodiments, the present disclosure is not limited to the foregoing embodiments, and may further include more other equivalent embodiments without departing from the concept of the present disclosure. The scope of the present disclosure is determined by the scope of the appended claims.

What is claimed is:

1. A semiconductor device, wherein the semiconductor device has a first active region and a second active region spaced apart from each other, and a passive region surrounding both the first active region and the second active region, and the semiconductor device comprises:
a substrate;
an epitaxial structure located on a side of the substrate, the epitaxial structure being provided with a two-dimensional electron gas, and the two-dimensional electron gas existing in the first active region and the second active region;
an electrode structure located on a side of the epitaxial structure away from the substrate, a portion of the electrode structure being located in the first active region, and another portion of the electrode structure being located in the passive region; and
at least one odd-mode resistor located outside the first active region and electrically connected to the electrode structure,
wherein each of the at least one odd-mode resistor comprises a first resistor electrode and a second resistor electrode, at least a portion of the first resistor electrode and at least a portion of the second resistor electrode are both located in the second active region, and in a same odd-mode resistor, the first resistor electrode and the second resistor electrode both form ohmic contact with the two-dimensional electron gas in the second active region; and along an arrangement direction of the first resistor electrode and the second resistor electrode, a two-dimensional-electron-gas conductive channel exists between the first resistor electrode and the second resistor electrode.

2. The semiconductor device according to claim 1, wherein in a same odd-mode resistor, a distance between the first resistor electrode and the second resistor electrode is d, and extension lengths of the first resistor electrode and the second resistor electrode are both w;
a contact resistance of the first resistor electrode is Rc1, a contact resistance of the second resistor electrode is Rc2, and a sheet resistance of the two-dimensional electron gas between the first resistor electrode and the second resistor electrode is Rsh; and
a resistance value R of the odd-mode resistor is equal to Rc1+Rc2+Rsh·d/W.

3. The semiconductor device according to claim 1, wherein the at least one odd-mode resistor comprises at least one first odd-mode resistor, the electrode structure comprises a gate electrode structure, the gate electrode structure comprises at least one gate electrode and a gate supply electrode, and each of the at least one gate electrode is spaced apart from the gate supply electrode; and
the first resistor electrode of the at least one first odd-mode resistor is electrically connected to the at least one gate electrode, and the second resistor electrode of the at least one first odd-mode resistor is electrically connected to the gate supply electrode.

4. The semiconductor device according to claim 3, wherein in a case that the at least one gate electrode comprises a plurality of gate electrodes, in a same first odd-mode resistor, the first resistor electrode is electrically connected to at least one of the plurality of gate electrodes, and the second resistor electrode is electrically connected to the gate supply electrode.

5. The semiconductor device according to claim 3, wherein in a case that the at least one gate electrode comprises a plurality of gate electrodes, one first odd-mode resistor is arranged between each of the plurality of gate electrodes and the gate supply electrode.

6. The semiconductor device according to claim 3, wherein the electrode structure further comprises a source electrode, and along a second direction, the source electrode is located between two adjacent gate electrodes; and
in a same first odd-mode resistor, the first resistor electrode is electrically connected to two gate electrodes disposed adjacent to the source electrode, and the second resistor electrode is electrically connected to the gate supply electrode.

7. The semiconductor device according to claim 3, wherein in a case that the at least one gate electrode comprises a plurality of gate electrodes, each of the plurality of gate electrodes extends along a first direction, the plurality of gate electrodes are arranged along a second direction, any two adjacent gate electrodes are symmetrically arranged about a symmetry axis, first odd-mode resistors electrically connected to the two adjacent gate electrodes symmetrically arranged are symmetrically arranged about the symmetry axis, the symmetry axis extends along the first direction, and the first direction and the second direction intersect and are both parallel to a plane where the substrate is located.

8. The semiconductor device according to claim 3, wherein the gate electrode comprises a gate main body portion and a gate tail portion connected to each other, the gate tail portion is located on a side of the gate main body portion close to the gate supply electrode, and along a second direction, an extension width of the gate tail portion is greater than an extension width of the gate main body portion; the second direction and an extension direction of the gate electrode intersect; and the gate tail portion is electrically connected to the first resistor electrode of a corresponding first odd-mode resistor.

9. The semiconductor device according to claim 3, wherein the gate supply electrode comprises a supply body portion and at least one supply protruding portion, the supply body portion and the at least one supply protruding portion are connected to each other, and the at least one supply protruding portion is located on a side of the supply body portion close to the gate electrode; and the second resistor electrode of each of the at least one first odd-mode resistor is electrically connected to a respective supply protruding portion.

10. The semiconductor device according to claim 3, wherein the electrode structure further comprises an ohmic electrode structure, the ohmic electrode structure comprises an ohmic electrode and an ohmic supply electrode connected to each other, each of at least one of the gate supply electrode or the ohmic supply electrode comprises at least two supply sub-portions, any two adjacent supply sub-portions of the at least two supply sub-portions are spaced apart from each other, and the at least one odd-mode resistor further comprises at least one second odd-mode resistor; and in a same second odd-mode resistor, the first resistor electrode is electrically connected to one of the at least two supply sub-portions, and the second resistor electrode is electrically connected to another of the at least two supply sub-portions.

11. The semiconductor device according to claim 1, wherein the at least one odd-mode resistor comprises at least one second odd-mode resistor, the electrode structure comprises at least one electrode and at least one supply electrode electrically connected to the at least one electrode, each of the at least one supply electrode comprises at least two supply sub-portions, and any two adjacent supply sub-portions of the at least two supply sub-portions are spaced apart from each other; and in a same second odd-mode resistor, the first resistor electrode is electrically connected to one of the at least two supply sub-portions, and the second resistor electrode is electrically connected to another of the at least two supply sub-portions.

12. The semiconductor device according to claim 11, wherein in a same supply electrode, the at least two supply sub-portions are arranged along a second direction, each of the at least two supply sub-portions comprises a supply main body portion and at least one supply interdigital portion, the supply main body portion is connected to the at least one supply interdigital portion, and along the second direction, the at least one supply interdigital portion is located on a side of the supply main body portion; and each of the at least one supply interdigital portion extends along the second direction, the at least one supply interdigital portion of one of two adjacent supply sub-portions and the at least one supply interdigital portion of the other of the two adjacent supply sub-portions are alternately arranged along a first direction; the first direction and the second direction intersect and are both parallel to a plane where the substrate is located; in a same second odd-mode resistor, the first resistor electrode and the second resistor electrode extend along the second direction and are arranged along the first direction; and in a same second odd-mode resistor and in a same supply electrode, the first resistor electrode is electrically connected to one of two adjacent supply interdigital portions, and the second resistor electrode is electrically connected to the other of the two adjacent supply interdigital portions.

13. The semiconductor device according to claim 11, wherein in a same supply electrode, two supply sub-portions adjacent to each other along a second direction each comprise at least two supply interdigital portions; in any two adjacent supply interdigital portions arranged along a first direction, one supply interdigital portion is electrically connected to the first resistor electrode of a corresponding second odd-mode resistor, and the other supply interdigital portion is electrically connected to the second resistor electrode of a corresponding second odd-mode resistor; the first direction and the second direction intersect and are both parallel to a plane where the substrate is located; and the at least one second odd-mode resistor comprises at least two second odd-mode resistors, and the at least two second odd-mode resistors are connected in parallel.

14. The semiconductor device according to claim 1, wherein the electrode structure comprises an ohmic electrode structure, the ohmic electrode structure comprises an ohmic electrode, and the first resistor electrode and the second resistor electrode of each of the at least one odd-mode resistor are both disposed in the same layer as the ohmic electrode.
